(19) United States
(12) Patent Application Publication
(10) Pub. No.: US 2007/0259509 A1
(43) Pub. Date: Nov. 8, 2007

(54) METHOD OF THINNING A WAFER

(76) Inventor: Chih-Ping Kuo, Kao-Hsiung City (TW)

Correspondence Address: NORTH AMERICA INTELLECTUAL PROPERTY CORPORATION, P.O. BOX 506, MERRIFIELD, VA, 22116, US

(21) Appl. No.: 11/425,130

(22) Filed: Jun. 19, 2006

(30) Foreign Application Priority Data
May 2, 2006 (TW) 095115615

(51) Int. Cl. H01L 21/30

(52) U.S. Cl. 438/459

(57) ABSTRACT

A method of thinning a wafer. A wafer is provided, and the front surface of the wafer is bonded to a carrier wafer with a bonding layer. The bonding layer is a thermal release tape or a UV tape. Subsequently, a wafer thinning process is performed to thin the wafer from the back surface.

### BACKGROUND OF THE INVENTION

1. Field of the Invention

The invention relates to a method of thinning a wafer, and more particularly, to a method of fixing a wafer onto a carrier wafer with a bonding layer, such as a thermal release tape or an ultraviolet (UV) tape, so as to increase the minimum thickness of wafer thinning.

2. Description of the Prior Art

In consideration of designated functions or desired size, many semiconductor components and micro-electromechanical components have to perform a wafer thinning process, so that the wafers are thinned into the desired sizes. Because the method of thinning a wafer is limited by the supporting mechanism, such as an electrostatic chuck, the wafers can only be thinned to a thickness of about 100 micrometers as the extreme. When the wafer is excessively thinned, breaks can easily occur.

### SUMMARY OF THE INVENTION

It is therefore an objective of the present invention to provide a method of thinning a wafer, so as to prevent the wafer from cracking, and increase the wafer's minimum thickness.

According to the present invention, a method of thinning a wafer is provided. First, a wafer is provided. Subsequently, a front surface of the wafer is bonded to a carrier wafer with a bonding layer, where the bonding layer is a thermal release tape or a UV tape. Next, a wafer thinning process is performed to thin the wafer from a back surface of the wafer.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1 to 10 are schematic diagrams illustrating a method of thinning a wafer according to a preferred embodiment of the present invention.

### DETAILED DESCRIPTION

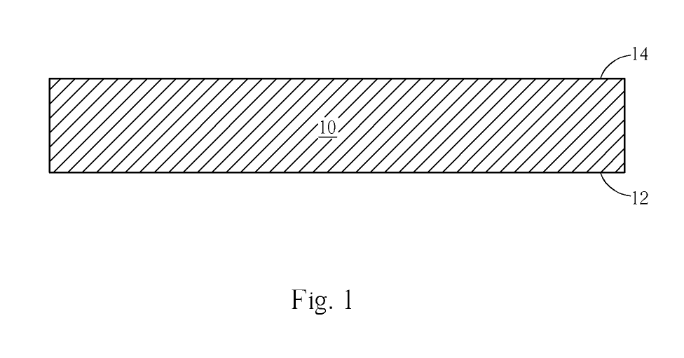

Please refer to FIGS. 1 to 10. FIGS. 1 to 10 are schematic diagrams illustrating a method of thinning a wafer according to a preferred embodiment of the present invention. As shown in FIG. 1, a wafer 10 is first provided, the wafer including a front surface 12 and a back surface 14. In this preferred embodiment, the wafer 10 is a wafer that already includes the needed semiconductor components or micro-electromechanical components (not shown in the figure) in its front surface 12, and also requires thinning. However, the method of the present invention is not limited by this preferred embodiment, and can be applied to any wafer thinning process in semiconductor processes or in micro-electromechanical processes.

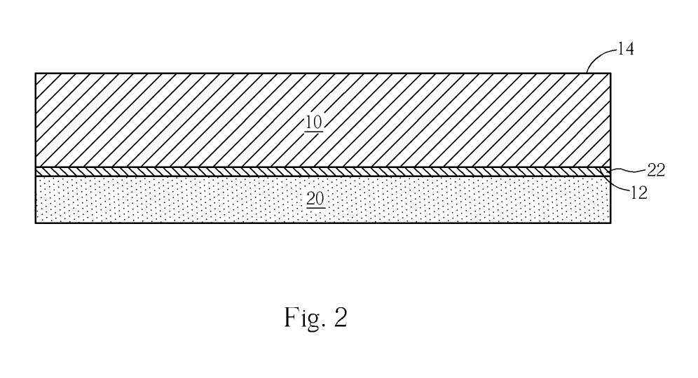

As shown in FIG. 2, a carrier wafer 20, such as a semiconductor wafer, a glass wafer, a plastic wafer, or a silicon wafer, is subsequently provided, and the front surface 12 of the wafer 10 is bonded to a surface of the carrier wafer 20 with a bonding layer 22. The present invention utilizes a thermal release tape or a UV tape to be the material of the bonding layer 22. The characteristic of the thermal release tape is that its adhering ability can be eliminated by heating. As a result, the wafer 10 can be easily separated from the surface of the carrier wafer 20 without damaging the wafer 10 when the temperature rises to the tape's release temperature (in a range about 150° C. to 200° C.). The adhering ability of the UV tape can be eliminated by exposing the UV tape to a UV ray within a specific range of wavelength. With the aforementioned characteristic of the UV tape, the wafer 10 can be easily separated from the surface of the carrier wafer 20 without damaging the wafer 10. Because the present invention utilizes the thermal release tape or the UV tape as the bonding layer 22, the wafer will not crack during the step of removing the bonding layer 22, even if the thickness of the wafer 10 is extremely thinned.

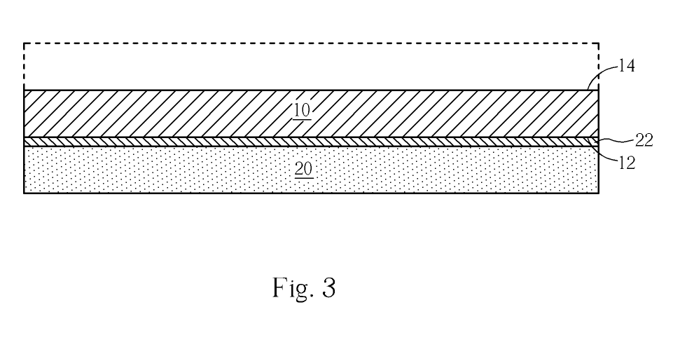

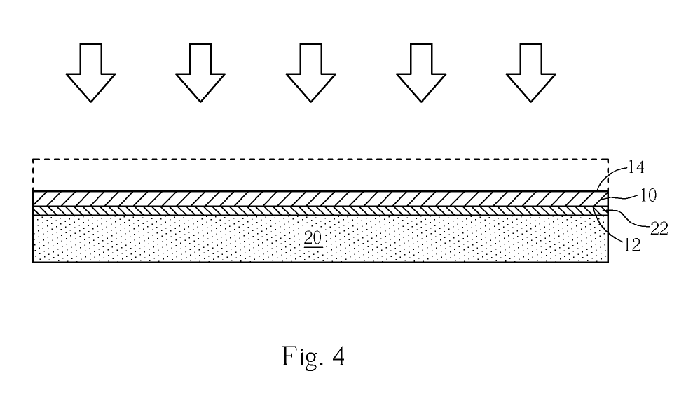

As shown in FIG. 3 and FIG. 4, a wafer thinning process is subsequently performed to thin the wafer 10 from the back surface 14 of the wafer 10 until the wafer 10 is thinned to its required thickness. In this preferred embodiment, the wafer thinning process can be divided into two steps. FIG. 3 illustrates the first step of the wafer thinning process, and FIG. 4 illustrates the second step of the wafer thinning process. In the first step shown in FIG. 3, the wafer 10 can be roughly thinned into a proper thickness by a relatively fast thinning treatment, such as a grinding process, as the wafer 10 is still significantly thick. For example, if the wafer 10 is a stander wafer with a diameter of 8 inches, the initial thickness of the wafer 10 is about 725 micrometers, and the wafer 10 can be rapidly thinned to a thickness of about 300 micrometers in the first step. In the second step shown in FIG. 4, the step can be performed utilizing a variety of treatments according to the needed final thickness, the required surface condition, the consideration of stress, and so on. For example, the entire wafer 10 can be thinned by a plasma etching process. The wafer 10 can also be etched by a chemical etching process, so that the back surface 14 of the wafer 10 can satisfy the required surface roughness. Otherwise, the wafer 10 can be treated by a buffing polishing process, so that the back surface 14 of the wafer 10 can have a desired surface smoothness. Of course, the second step of the wafer thinning process is not limited to use only one of the aforementioned treatments, but can perform any combination of the aforementioned treatments as required. Furthermore, other wafer thinning technologies, such as chemical mechanical polishing (CMP) process, can also be applied. Because the present invention utilizes the grinding process in the first step of the wafer thinning process, the efficiency of wafer thinning is improved. Because the second step of the wafer thinning process utilizes the above-mentioned treatments, such as the etching process, the buffing polishing process, and so on, the residual stress of the wafer due to the grinding process is eliminated, and the wafer can further satisfy a variety of specifications.

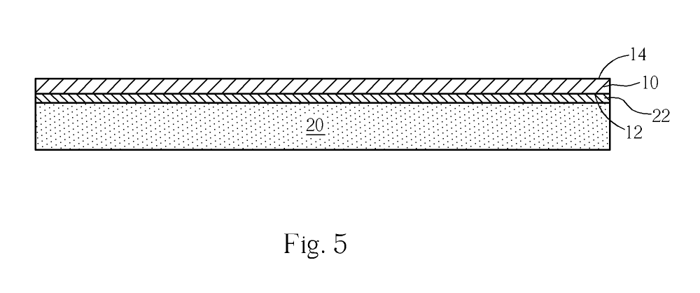

As shown in FIG. 5, after the second step of the wafer thinning process is performed, the thickness of the wafer 10 may be measured by a thickness measuring instrument, or the surface condition of the wafer 10 may be checked by an inspecting instrument. If the thickness or the surface condition of the wafer 10 falls short of desired requirements, the wafer thinning process can be re-performed until the wafer satisfies the predetermined specifications.

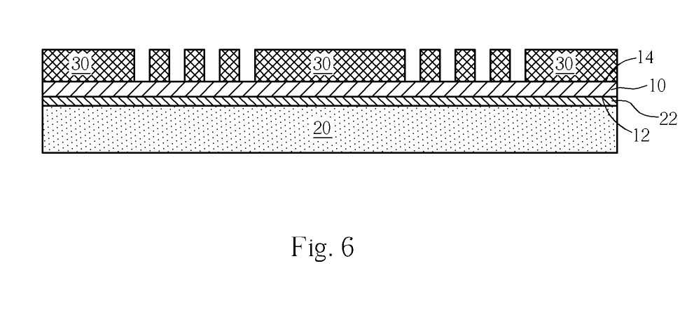

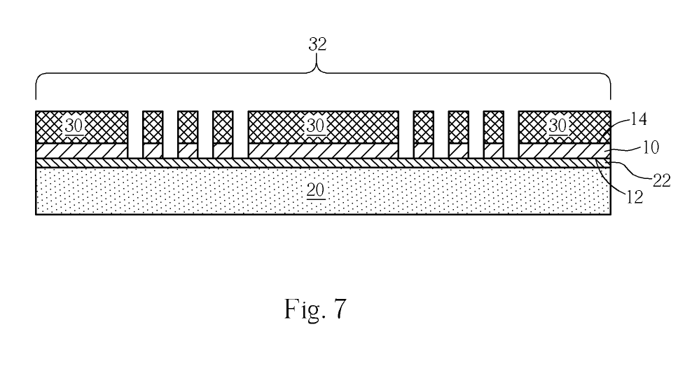

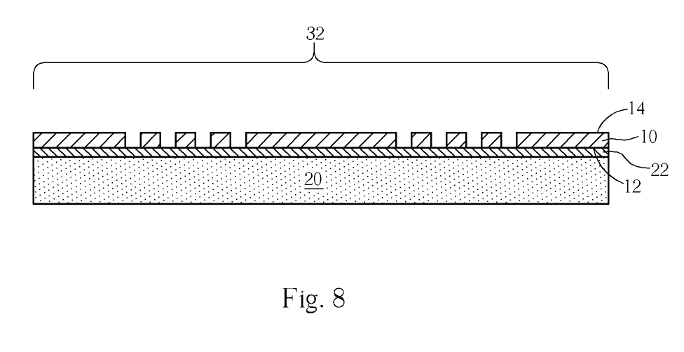

The wafer thinning process of the present invention can thin the wafer 10 to a thickness of about 50 micrometers or even thinner. This thickness of the wafer 10 therefore is thinner than the general ultra-thin wafer (about 100 micrometers), and has an increased extreme thinness. Some components, such as the micro-electromechanical components, or particular back side patterns, such as the back cavity of a mike component, may be indispensable on the back surface 14 of the wafer 10. For such circumstances, the present invention may further perform the following processes after the wafer thinning process. As shown in FIG. 6, a mask pattern 30, such as a photoresist pattern, is formed on the back surface 14 of the wafer 10, so as to define a needed back side pattern. As shown in FIG. 7, thereafter, an anisotropic etching process, such as a plasma etching process, is performed to etch parts of the wafer 10 that are not covered by the mask pattern 30. A back side pattern 32 is thereby formed on the back surface 14 of the wafer 10. As shown in FIG. 8, the mask pattern 30 is removed afterward. It should be noted that the wafer 10 is etched by the anisotropic etching process in this preferred embodiment, in order that a wafer segmenting process can be integrated into the method of the present invention. In other words, a wafer segmenting process can also be performed in the step of forming the back side pattern 32, so as to divide the wafer 10 into a plurality of components. The method of the present invention therefore further enables a wafer level segmenting method.

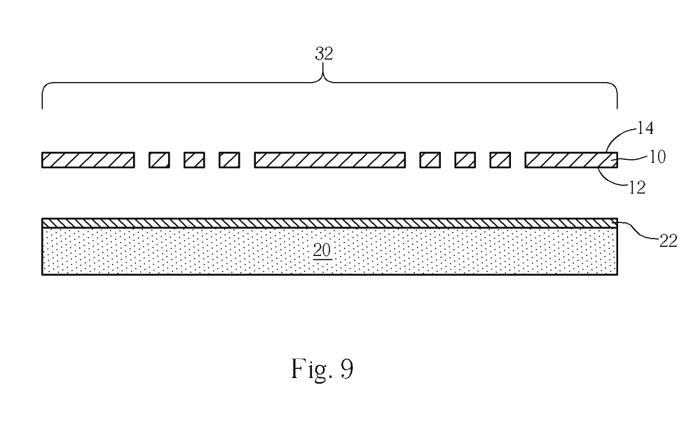

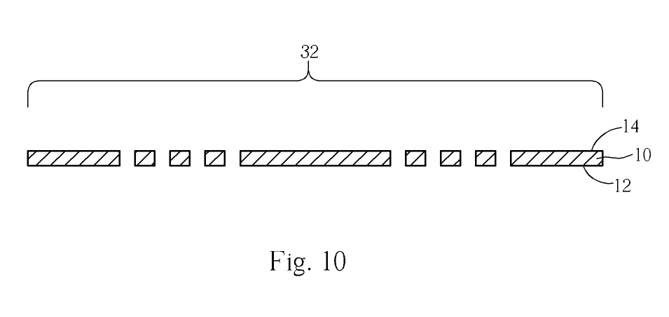

As shown in FIG. 9, after the back side pattern 32 is formed, the adhering ability of the bonding layer 22 should be eliminated, so as to separate the wafer 10 from the surface of the carrier wafer 20. As mentioned above, if the bonding layer 22 is a thermal release tape, the tape's adhering ability is eliminated by heating at a temperature higher than its release temperature. As a result, the wafer 10 is easily separated from the surface of the carrier wafer 20 without damaging the wafer 10. If the bonding layer 22 is a UV tape, the adhering ability of the UV tape is eliminated by exposure to a UV ray, and the wafer 10 can therefore be easily separated from the surface of the carrier wafer 20 without damaging the wafer 10. As shown in FIG. 10, finally, the back surface 14 of the wafer 10 includes the back side pattern 32, the wafer 10 has a thickness about 50 micrometers, and the wafer 10 is not broken due to the use of the thermal release tape or the UV tape.

In sum, the method of the present invention for thinning a wafer has the following advantages:

(1) The wafer is bonded to the carrier wafer utilizing thermal release tape or UV tape. This feature can effectively protect the components on the front surface of the wafer, and solve the problem of difficult fixing during wafer transferring after the wafer thinning process.

(2) The follow-up processes can be performed to the thinned wafer without removing the thermal release tape or the UV tape. This prevents the wafer from damage.

(3) The wafer thinning process can be adjusted by the required specifications, so the problem of stress can be effectively solved.

(4) The adhering ability of the thermal release tape or the UV tape can be easily eliminated, thereby preventing the wafer from cracking.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method of thinning a wafer comprising:
providing the wafer;
bonding a front surface of the wafer to a carrier wafer with a bonding layer, the bonding layer comprising a thermal release tape or an ultraviolet (UV) tape; and
performing a wafer thinning process to thin the wafer from a back surface of the wafer.

2. The method of claim 1, wherein the wafer thinning process comprises a plasma etching process.

3. The method of claim 1, wherein the wafer thinning process comprises a buffing polishing process.

4. The method of claim 1, wherein the wafer thinning process comprises a chemical etching process.

5. The method of claim 1 further comprising a step of performing a thickness measuring process to the wafer after the step of performing the wafer thinning process.

6. The method of claim 1 further comprising a step of forming a back side pattern on the back surface of the wafer after the step of performing the wafer thinning process.

7. The method of claim 6, wherein the step of forming the back side pattern comprises:
forming a mask pattern on the back surface of the wafer;
performing an etching process to etch parts of the wafer that are not covered by the mask pattern; and
removing the mask pattern.

8. The method of claim 7, wherein the etching process comprises an anisotropic etching process.

9. The method of claim 7, wherein the etching process etches through the wafer.

10. The method of claim 6 further comprising a step of removing the bonding layer to separate the wafer from the carrier wafer after the step of forming the back side pattern.
